(19) United States
(12) Patent Application Publication
(10) Pub. No.: US 2004/0223193 A1
(43) Pub. Date: Nov. 11, 2004

(54) Image reading apparatus and control chip

(75) Inventor: Hideki Sawada, Kyoto (JP)

Correspondence Address: MERCHANT & GOULD PC, P.O. BOX 2903, MINNEAPOLIS, MN, 55402-0903, US

(73) Assignee: ROHM CO., LTD., Kyoto-shi (JP)

(21) Appl. No.: 10/821,713

(22) Filed: Apr. 9, 2004

(30) Foreign Application Priority Data
Apr. 10, 2003 (JP) 2003-105987

(51) Int. Cl. H04N 1/04; G03F 3/08

(52) U.S. Cl. 358/483; 358/513

(57) ABSTRACT

An image reading apparatus includes image sensor chips and control chips for controlling the operation of the image sensor chips. Each image sensor chip, including a plurality of photoelectric converters, performs the outputting and resetting of accumulated electric charge due to light detection. Each control chip includes resolution data input terminals for inputting resolution data to specify resolution, and also a reset signal generator for generating a reset signal for performing the resetting of the accumulated electric charge. The reset signal is generated in a selected one of the cycles that corresponds to the resolution data inputted into the terminals.

### BACKGROUND OF THE INVENTION

1. Field of the Invention

The present invention generally relates to an image reading apparatus provided with image sensor chips. In particular, the invention relates to a control chip for controlling the image sensor chips of an image reading apparatus.

2. Description of the Related Art

A conventional image reading apparatus may incorporate a plurality of CCD image sensor chips for detection of image reading light. Typically, in such a reading apparatus, the operation of the CCD image sensor chips is regulated by a plurality of control chips which are also incorporated in the apparatus.

It is often desired by the user that an image reading apparatus can change the image reading resolution in light of the use, for example. To provide adjustable resolution, an image reading apparatus may incorporate a reset signal controller in addition to the control chips mentioned above, for generating a charge reset signal at regular intervals corresponding to the required resolution. More specifically, each CCD image sensor chip is designed to output and reset the electric charge accumulated through the light detection by the photodiodes. The resetting of the charge is performed when a charge reset signal from the reset signal controller is inputted to the CCD sensor chip. The reset signal controller can generate reset signals in a selected one of the predetermined cycles so that the resolution can be changed by changing the cycle of the reset signals.

In the prior art image reading apparatus, as noted above, the driving of the CCD image sensor chips and the generation of the charge reset signals are controlled by two different units, i.e., the control chips and the reset signal controller. Unfavorably, such a separate control arrangement tends to entail discrepancy of operation timing between the CCD sensor chips and the reset signal controller, particularly when the image reading is performed at high speed. Such an asynchronous operation hinders the generation of proper image signals, which leads to poor image quality.

### SUMMARY OF THE INVENTION

The present invention has been proposed under the circumstances described above. It is therefore an object of the present invention to provide an image reading apparatus with which the adjustment of the resolution can be performed properly without entailing asynchronous input of a reset signal into the image sensor chip. Another object of the present invention is to provide an image sensor control chip advantageously used in such an image reading apparatus.

According to a first aspect of the present invention, there is provided an image reading apparatus including: a plurality of image sensor chips each of which includes a plurality of photoelectric conversion elements and performs outputting of electric charge accumulated due to light received by the photoelectric conversion elements and resetting of the accumulated electric charge; and a plurality of control chips for controlling operation of the image sensor chips. Each of the control chips includes a resolution data input section to which resolution data to specify resolution is inputted. The control chip also includes a reset signal generator for generating a reset signal for performing the resetting of the electric charge in a cycle corresponding to the resolution data inputted into the resolution data input section.

With this arrangement, when resolution data to specify the desired resolution is inputted to the resolution data input section of a control chip, the reset signal generator generates a reset signal in a cycle corresponding to the resolution data. By supplying the generated reset signal to the image sensor chip, the image signals at the selected resolution are obtained. In this manner, the resolution for image reading can be easily changed by changing the resolution data to be inputted into the control chip. The control chip may be designed to generate the reset signals in parallel with the generation of other signals for controlling the driving of the image sensor chip. Further, the reset signals can be generated by utilizing the signals for controlling the driving of the image sensor chip or the clock signals serving as the base for generating such signals. Therefore, the synchronization of the reset signals with the signals for controlling the driving of the image sensor chip can be attained easily. As a result, the timing deviation in generating reset signals does not occur even when image reading is performed at high speed.

Preferably, each of the control chips may comprise a resolution void terminal for selectively inhibiting image reading at a predetermined resolution. Specifically, the image reading at the predetermined resolution may be inhibited when the resolution void terminal is held in a first wiring state, while the reading may be enabled when the resolution void terminal is held in a second wiring state different from the first wiring state. The first wiring state may be a state in which the resolution void terminal is kept open (non-connected), while the second wiring state may be a state in which the resolution void terminal is grounded. Alternatively, in the first wiring state the terminal may be grounded, while in the second wiring state the terminal may be open. The inhibited resolution may be the highest resolution among the predetermined options, the lowest resolution, or any other intermediate resolution between them.

With the above arrangement, it is possible to inhibit the image reading at a certain resolution without changing the hardware structure of the control chips. With the use of such control chips, image reading apparatuses which differ in resolution can be readily provided.

Preferably, the resolution data input section may comprise a first input terminal and a second input terminal. Each of the control chips may be selectively set to a first mode and a second mode: the first mode permitting parallel input of the resolution data into the first input terminal and the second input terminal, the second mode permitting serial input of the resolution data into the second input terminal. With this arrangement, the resolution data input into the control chip can be properly performed regardless of whether the data input is performed in parallel (i.e., via both terminals) or serially (via only one of the two terminals).

Preferably, each of the control chips may comprise a mode setting terminal for selecting one of the above-mentioned first and second modes. This selection may be made depending on the wiring condition of the mode setting terminal. For instance, it may be arranged that the first mode (or second mode) is selected when the mode setting terminal is grounded. With this arrangement, the mode setting can be performed readily.

Preferably, the image reading at a predetermined resolution may be inhibited when the second mode is selected and the first input terminal is held in a predetermined wiring state (non-connected, grounded, etc.). With this arrangement, the inhibition of resolution is realized by using the existing first input terminal, and no additional terminal need be provided for the inhibition.

Preferably, each of the image sensor chips may be a CCD image sensor chip including photodiodes, a line memory and an analog shift register. Further, each of the control chips may generate signals for causing the photodiodes to transmit electric charge to the line memory and the analog shift register and may also generate signals for causing the analog shift register to output signals. The signals outputted from the analog shift register are inputted into the control chip.

Preferably, the control chips may include amplifiers for amplifying signals outputted from the image sensor chips, and a reference voltage from a common power supplier may be applied in parallel to the respective amplifiers. With this arrangement, the amplifiers can receive the same or substantially the same reference voltage, which contributes to the reduction of offset voltage for the amplifiers.

According to a second aspect of the present invention, there is provided a control chip for controlling the driving of an image sensor chip. The control chip comprises: a resolution data input section to which resolution data to specify resolution is inputted; and a reset signal generator for generating a reset signal for causing the image sensor chip to reset accumulated electric charge in a cycle corresponding to the resolution data inputted into the resolution data input section.

Preferably, the control chip of the present invention may further comprise a resolution void terminal for inhibition of a selected image reading resolution. The image reading at a predetermined resolution is inhibited when the resolution void terminal is held in a predetermined wiring state.

Other features and advantages of the present invention will become clearer from the description given below with reference to the accompanying drawings.

### BRIEF DESCRIPTION OF THE DRAWINGS

FIG. 1 is a plan view illustrating an example of image reading apparatus according to the present invention;

FIG. 2 is a plan view illustrating a principal portion of the image reading apparatus of FIG. 1;

FIG. 3 illustrates examples of CCD image sensor chip and control chip according to the present invention;

FIG. 4 illustrates a time chart showing an example of signal waveform when the resolution is 1200 dpi;

FIG. 5 illustrates a time chart showing an example of signal waveform when the resolution is 600 dpi;

FIG. 6 illustrates a time chart showing an example of signal waveform when the resolution is 300 dpi;

FIG. 7 illustrates a time chart showing an example of signal waveform when the resolution is 200 dpi;

FIG. 8 is a plan view illustrating another example of image reading apparatus according to the present invention; and

FIG. 9 is a plan view illustrating a principal portion of the image reading apparatus of FIG. 8.

### DETAILED DESCRIPTION OF THE PREFERRED EMBODIMENTS

Preferred embodiments of the present invention will be described below with reference to the accompanying drawings.

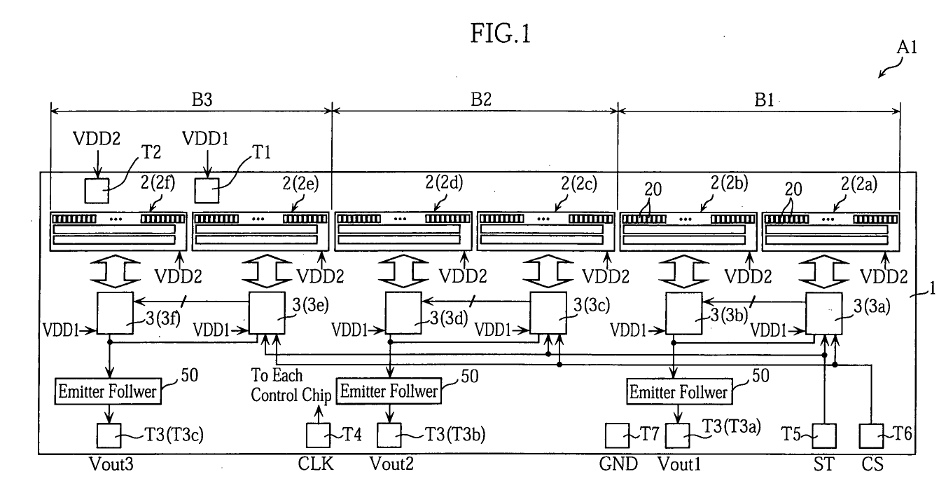

FIG. 1 illustrates an example of image reading apparatus according to the present invention. The image reading apparatus A1 includes a substrate 1, a plurality of CCD image sensor chips 2 (hereinafter abbreviated as “CCD chips”) and a plurality of control chips 3. The number of CCD chips 2 is made equal to the number of control chips 3 so that each control chip 3 controls the driving of a respective CCD chip 2. In this embodiment, six CCD chips 2a-2f and six control chips 3a-3f are provided. In the image reading apparatus A1, the resolution can be switched between four options, i.e. 1200 dpi (47.244 dots/mm), 600 dpi (23.622 dots/mm), 300 dpi (11.811 dots/mm) and 200 dpi (7.874 dots/mm), as will be described later.

The CCD chips 2 (and the control chips 3 as well) are aligned longitudinally of the substrate 1. The CCD chips 2 and the control chips 3 are divided into a first through a third blocks B1-B3 each consisting of two CCD chips 2 and two control chips 3. The image reading operation in the respective blocks B1-B3 can be performed simultaneously, whereby the time taken for image reading for one line can be shortened.

The substrate 1 is provided with a plurality of terminals T1-T7. The terminal T1 is connected to a power source for driving the control chips 3, and a voltage VDD1 of e.g. 5V is applied to the terminal T1. The electric power applied to the terminal T1 is supplied to each of the control chips 3, so that the voltage VDD1 is applied to each of the control chips 3. The terminal T2 is connected to a power source for driving the CCD sensor chips 2, and a voltage VDD2 of e.g. 12V is applied to the terminal T2. The terminals T3 (T3a, T3b and T3c), which serve to output image signals Vout1-Vout3, are connected, via emitter followers 50, to second control chips 3b, 3d and 3f of the blocks B1-B3, respectively. The image signals Vout1-Vout3 outputted from the terminals T3 are inputted into an external controller (not shown). The controller, which has e.g. a signal processing function, a signal generating function and a computing function, controls the entire operation of the image reading apparatus A1.

The terminal T4 serves to input a clock signal. The clock signals inputted into the terminal T4 are fed to each of the control chips 3. The terminal T5 receives start pulses ST from the controller. The start pulses ST serve as a trigger for starting waveform generation and are inputted through the terminal T5 into the control chips 3a, 3c and 3e. The terminal T6 serves to receive resolution data CS from the controller, and the received resolution data CS is inputted into the control chips 3a, 3c and 3e. The terminal T7 is for ground connection.

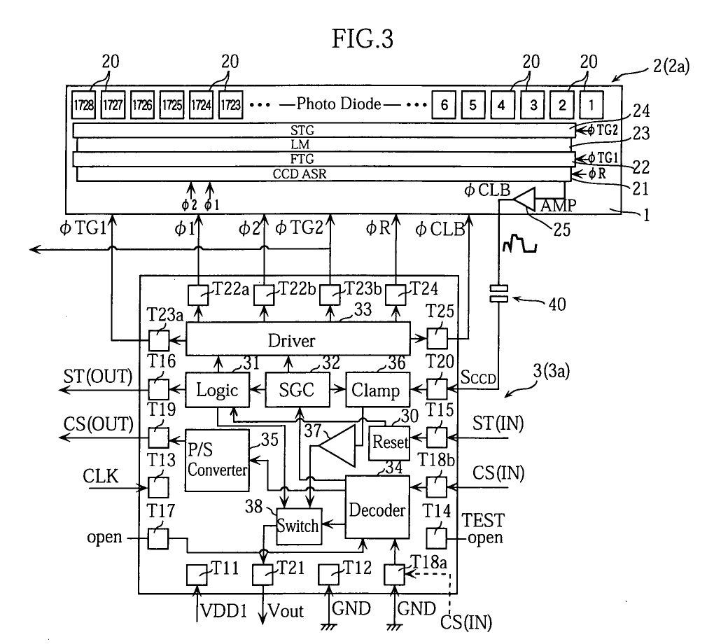

As the CCD chips 2, use may be made of conventionally known CCD image sensor chips. As shown in FIG. 3, each of the CCD chips 2 include 1728 photodiodes 20 arranged in a row, an analog shift register (ASR) 21, a first transfer gate (FTG) 22, a line memory (LM) 23, a second transfer gate (STG) 24 and an amplifier 25.

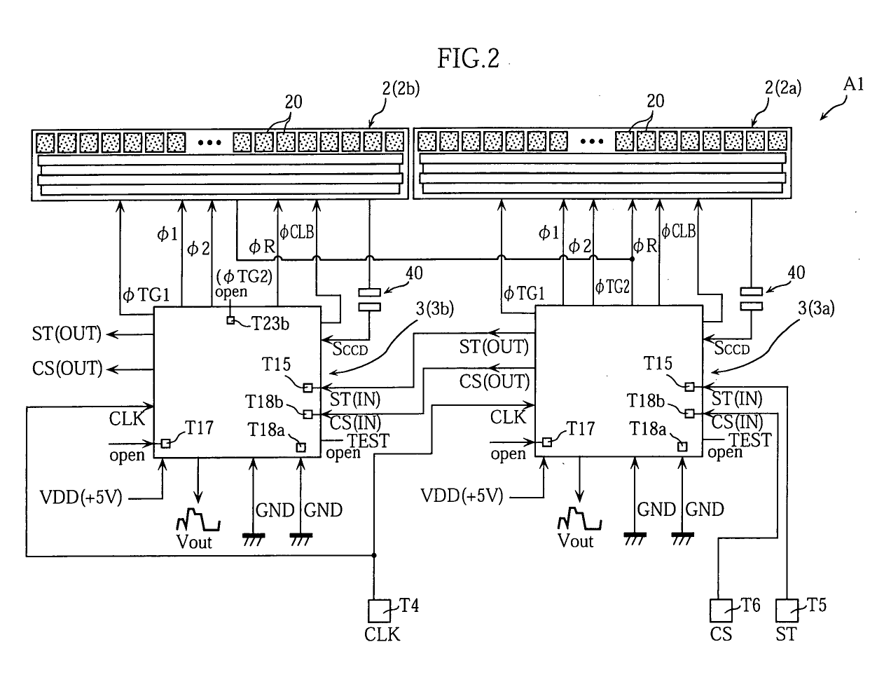

The paired control chips 3 in each block B1-B3 (see FIG. 2) are partially different from each other in wiring pattern. However, the respective control chips 3 have the same hardware structure. Specifically, as shown in FIG. 3, each of the control chips 3 is an IC chip incorporating various circuits and includes a power supply terminal T11, a ground connection terminal T12, a clock input terminal T13, a test terminal T14, a start pulse input terminal T15, a start pulse output terminal T16, a mode setting terminal T17, a first and a second resolution data input terminals T18a and T18b, a resolution data output terminal T19, a CCD input terminal T20, an image signal output terminal T21, a first and a second shift register/clock output terminals T22a and T22b, a first and a second transfer gate pulse output terminals T23a and T23b, a reset pulse output terminal T24 and a clamp pulse output terminal 25.

The power supply terminal T11 serves to supply electric power necessary for driving the control chip 3. A voltage VDD1 is applied to the power supply terminal T11 through the terminal T1 on the substrate 1. The ground connection terminal T12 is connected to the ground terminal T7 on the substrate 1. The clock input terminal T13 serves to input clock signals CLK of 1-10 MHz, for example, and is connected to the terminal T4 on the substrate 1. Based on the clock signals CLK, various timing pulse signals such as a shift register/clock signal is generated. The test terminal T14 is utilized for testing the control chip 3 and is kept open in a normal state after the test is finished.

The start pulse input terminal T15 serves to receive a start pulse ST from the terminal T5 on the substrate 1. As noted above, the start pulse ST serves as a trigger for starting waveform generation and is inputted into a reset circuit 30. The combination of the reset circuit 30 as well as a logic circuit 31 and a signal generation circuit 32 serves to generate various kinds of signals based on the start pulse ST, which will be described later. The start pulse output terminal T16 serves to output the start pulse ST to the subsequent control chip.

The first and the second resolution data input terminals T18a and T18b serve to input resolution data CS for specifying the resolution. The mode setting terminal T17 serves to set a data input mode for inputting the resolution data to the first and the second resolution data input terminals T18a and T18b. Specifically, two options are provided as the resolution data input mode, which are a first mode in which the resolution data CS is inputted into the first and the second resolution data input terminals T18a and T18b as parallel input, and a second mode in which the resolution data CS is serially inputted into the second resolution data input terminal T18b. The resolution data input mode is set to the first mode when the mode setting terminal T17 is connected to ground and set to the second mode when the mode setting terminal T17 is made open.

In the first mode, totally 2-bit of data (1 bit for each terminal) for specifying resolution is inputted into the terminals T18 and T18b as parallel input. Using the 2-bit signals, four kinds of resolution is made distinguishable from each other. For instance, the resolution of 1200 dpi may be represented as (H, H), the resolution of 600 dpi as (H, L), the resolution of 300 dpi as (L, H) and the resolution of 200 dpi as (L, L), as shown in Table 1.

TABLE 1
Mode Setting Terminal: Connected to Ground (Parallel Input)

| Terminal T18a | Terminal T18b | Resolution (dpi) |
|---|---|---|
| H | H | 1200 |
| H | L | 600 |
| L | H | 300 |
| L | L | 200 |

In the second mode, 2-bit of serial data for specifying the resolution is serially inputted into the second resolution data input terminal T18b. In the second mode, the first resolution data input terminal T18a is utilized for switching between a state in which the image reading at the highest resolution of 1200 dpi is allowed (enabled) and another state in which the reading with the highest resolution is inhibited. Specifically, as shown in Table 2 below, the resolution data of (H, H) to be serially inputted into the second terminal T18b represents 1200 dpi, (H, L) represents 600 dpi, (L, H) represents 300 dpi and (L, L) represents 200 dpi.

TABLE 2
Mode Setting Terminal: Open (Serial Input to Terminal T18b)

| Terminal T18a | Terminal T18b | Resolution (dpi) |
|---|---|---|
| L | H, H | 1200 |
| L | H, L | 600 |
| L | L, H | 300 |
| L | L, L | 200 |
| OPEN | H, H | Output Inhibited |
| OPEN | H, L | 600 |
| OPEN | L, H | 300 |
| OPEN | L, L | 200 |

In the above instance, the image reading at the resolution of 1200 dpi is allowed only when the first resolution data input terminal T18a is set to “L”, i.e. connected to ground. When the first terminal T18a is open, the image reading at 1200 dpi is inhibited. In the illustrated embodiment, the first terminal T18a is connected to ground so that the image reading at 1200 dpi is possible.

Further, in the embodiment, the mode setting terminal T17 in each of the control chips 3a-3f is open to select the second mode. The mode setting terminal T17 is pulled-up in the control chip 3. When the terminal T17 is connected to ground, a constant current flows within the control chip 3 toward the ground connection terminal T12.

The first and the second resolution data input terminals T18a and T18b are connected to a decoder 34. The above-noted resolution data CS is inputted into and decoded by the decoder 34. The decoded resolution data CS is then supplied to the signal generation circuit 32. The decoded data is also inputted into a parallel/serial converter 35 and then outputted, as serial resolution data CS, to the subsequent control chip 3 through the resolution data output terminal T19.

The first and the second shift register/clock output terminals T22a, T22b serve to output CCD register transfer pulse signals Φ1 and Φ2, respectively, to the relevant CCD chip 2. The first transfer gate pulse output terminal T23a serves to output a timing pulse signal ΦTG1 for transferring the charge accumulated in the line memory 23 of the CCD chip 2 to the CCD analog shift register 21. The second transfer gate pulse output terminal T23b serves to output a timing pulse signal ΦTG2 for transferring the charge accumulated in the photodiodes 20 of the CCD chip 2 to the line memory 23. The clamp pulse output terminal T25 serves to output a timing pulse signal ΦCLB for clamping a signal outputted from the CCD analog shift register 21 of the CCD chip 2. During the clamping, the pulse signal ΦCLB is at a low level. The reset pulse output terminal T24 serves to output a reset signal ΦR for resetting a signal of each pixel of the CCD chip 2. During the resetting, the reset signal ΦR is at a high level. For instance, the reset signal ΦR is generated at the signal generation circuit (SGC) 32 and outputted through the driver circuit 33. These circuits are an example of reset signal generator of the present invention.

The signal generation circuit 32 has a function to divide signals of a certain cycle to generate plural kinds of reset signals ΦR of different cycles. Specifically, in accordance with the 2-bit resolution data CS inputted into both or one of the first and the second resolution data input terminals T18a and T18b, the signal generation circuit 32 generates reset signals ΦR of a cycle which enables the outputting of image signals at one of the resolutions 1200 dpi, 600 dpi, 300 dpi and 200 dpi.

The CCD input terminal T20 serves to input the signals (image signals) S_{CCD} outputted from the relevant CCD chip 2 into the control chip 3. The CCD input terminal T20 is connected to the CCD chip 2 via a coupling capacitor 40. The signals S_{CCD} inputted through the CCD input terminal T20 is clamped by a clamping circuit 36 and then amplified by an amplifier 37 having a buffer function. A predetermined reference voltage is applied to the amplifier 37. An equal or generally equal reference voltage is applied to each of the amplifiers 37 of the control chips 3a-3f, which is realized by supplying the voltage VDD1 applied to the terminal T1 to each of the control chips 3a-3f in parallel. With this arrangement, the offset voltage of the amplifier 37 in each of the control chips 3a-3f can be reduced. The signals amplified by the amplifier 37 are fed to a switch circuit 38. Among such signals, only those which are determined as effective by the switch circuit 38 are outputted through the image signal output terminal T21 toward the terminal T3 on the substrate 1 as image signals Vout.

As shown in FIG. 2, the second control chip 3b receives a start pulse ST and resolution data CS inputted from the control chip 3a through the start pulse input terminal T15 and the second resolution data input terminal T18b, respectively. Further, the second CCD chip 2b receives a timing pulse signal ΦTG2 from the control chip 3a. Therefore, the second transfer gate pulse output terminal T23b of the control chip 3b is open. Apart from these points, the control chip 3b is the same in arrangement as the control chip 3a. The first control chips 3c and 3e of the second and the third blocks B2 and B3 are constituted similarly to the control chip 3a, whereas the second control chip 3d and 3f of the second block B2 and the third blocks B2 and B3 are constituted similarly to the control chip 3b.

The operation and advantages of the image reading apparatus A1 will be described below.

For easier understanding, the operation will be described with respect to the first block B1 only. When a start pulse ST is inputted into the start pulse input terminal T15 of the control chip 3a, the reset circuit 30, the logic circuit 31 and the signal generation circuit 32 begin to operate to generate pulse signals Φ1, Φ2, ΦTG1, ΦTG2 and ΦCLB by using the start pulse as a trigger for the waveform generation. Meanwhile, the second resolution data input terminal T18b receives resolution data CS for specifying the resolution as 2-bit serial data, based on which the signal generation circuit 32 generates reset signals ΦR in a cycle corresponding to the specified resolution. The reset signals ΦR as well as the above-noted pulse signals are inputted into the relevant CCD chip 2.

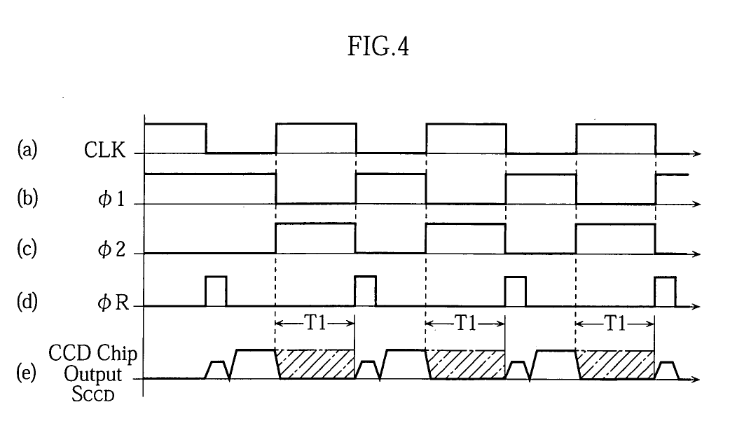

FIGS. 4-7 illustrate specific examples of clock signals CLK, CCD register transfer pulse signals Φ1 and Φ2, reset signals ΦR, and signals S_{CCD} outputted from the CCD chip 2. Shown in FIG. 4 is the case where the resolution data CS for 1200 dpi is inputted. In the CCD chip 2, the electric charge accumulated as the photodiodes 20 receive light is reset every time the reset signal ΦR is ON, and the accumulation of the electric charge is restarted when the reset signal ΦR is OFF. This operation is repeated in the CCD chip 2, and the electric charge accumulated before each time of resetting is amplified by the amplifier 25 and outputted as a signal S_{CCD}.

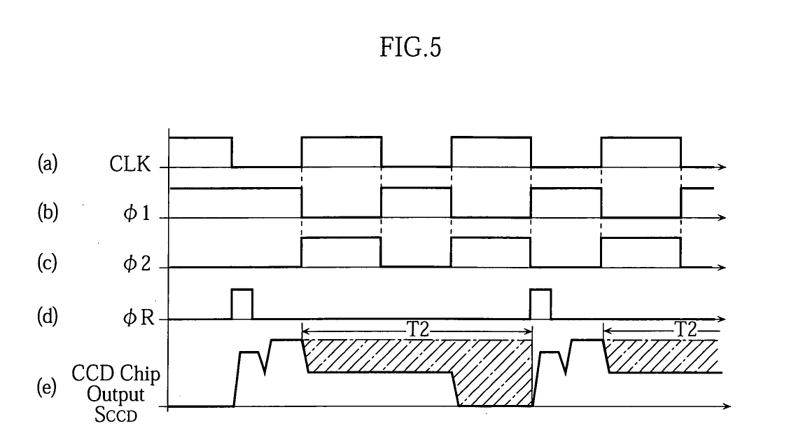

In the example shown in FIG. 4, the reset signals ΦR become ON (high level) in the same cycle as the signals CLK, Φ1 and ΦR. Therefore, the electric charge accumulated in each of the photodiodes 20 can be outputted individually. Accordingly, image signals for 1728 pixels can be outputted individually, which realizes image reading at 1200 dpi. In the control chip 3, the switch circuit 38 picks up effective signals from those clamped by the clamping circuit 36 and amplified by the amplifier 37. Specifically, among the signals S_{CCD} shown in FIG. 4, the electric charge accumulated in a predetermined period T1 before each time of resetting (electric charge at the hatched portion) corresponds to a respective image signal outputted from the control chip 3. (This holds true for FIGS. 5-7.)

FIG. 5 shows the case where the resolution data CS for 600 dpi is inputted. In this instance, the period of the reset signals ΦR is twice that of the reset signals at 1200 dpi shown in FIG. 4. Therefore, within the predetermined time T2 before each resetting, electric charge corresponding to two pixels is accumulated. By collectively outputting such electric charge, the resolution of 600 dpi is realized.

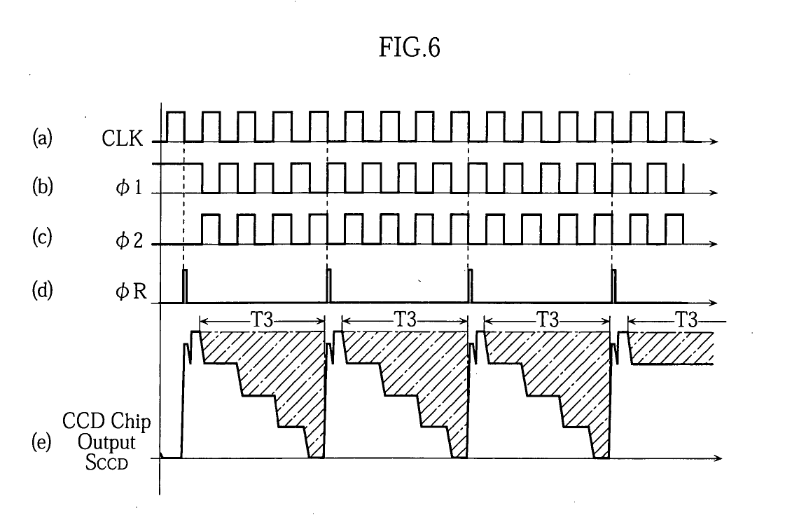

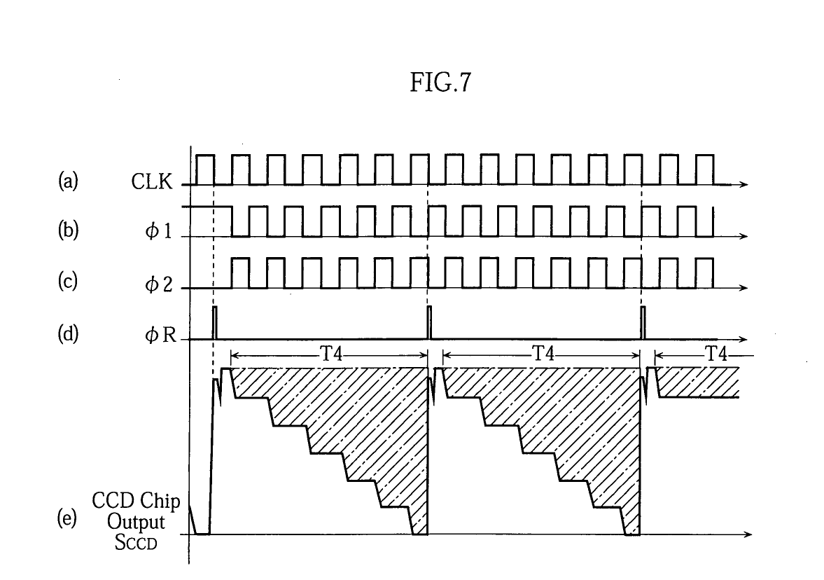

FIG. 6 shows the case where the resolution data CS is for 300 dpi. In this instance, the period of the reset signals ΦR is four times that of the reset signals at 1200 dpi shown in FIG. 4. Therefore, within the predetermined time T3 before each resetting, electric charge corresponding to four pixels is accumulated for collective output. FIG. 7 shows the case where the resolution data CS is for 200 dpi. In this instance, the period of the reset signals ΦR is six times that of the reset signals at 1200 dpi shown in FIG. 4. Therefore, within the predetermined time T4 before each resetting, electric charge corresponding to six pixels is accumulated for collective output.

After the signal S_{CCD} is outputted from the CCD chip 2a, a start pulse ST is outputted from the start pulse output terminal T16 to the control chip 3b. Further, the resolution data CS is outputted serially from the resolution data output terminal T19 of the control chip 3a to the second resolution data input terminal T18b of the control chip 3b. Thus, the control chip 3b performs the same operation as that of the control chip 3a described above. As a result, following the CCD chip 2a, the CCD chip 2b also outputs signals S_{CCD} to the control chip 3b for a desired resolution. While the above-described operation is performed in the first block B1, the same operation is performed simultaneously in the second and the third blocks B2 and B3. As a result, the image reading for one line can be finished quickly.

As noted above, by inputting the resolution data into the control chip 3, reset signals ΦR are generated in a cycle corresponding to the specified resolution. Each of the control chips 3 generates various pulse signals, other than the reset signals ΦR, for driving the CCD chip 2 based on the clock signals CLK. Therefore, synchronization of the reset signals ΦR with such pulse signals can be performed accurately and easily, whereby timing deviation of the reset signals ΦR during high-speed reading can be avoided. Further, since the generation of various signals necessary for driving the CCD chip 2 is performed collectively in the control chip 3, the structure of the image reading apparatus A1 can be simplified, which leads to the reduction of the manufacturing cost.

In the foregoing embodiment, the first resolution data input terminal T18a of the control chip 3 is grounded for enabling image reading at the resolution of 1200 dpi. When the first resolution data input terminal T18a is open, on the other hand, the control chip 3 does not perform the operation necessary for enabling the image reading at 1200 dpi. Thus, the image reading apparatus A1 can be easily changed to a simple selection mode in which only the three resolutions 600 dpi, 300 dpi and 200 dpi are available. At the resolution of 1200 dpi, the signal level for each pixel is lower than at the resolution of 600 dpi, for example, so that the read image is likely to become dark. The formation of such a dark image can be prevented by inhibiting the use of the 1200 dpi image reading. For degradation of the image sharpness, on the other hand, the image reading at the lowest resolution may be inhibited.

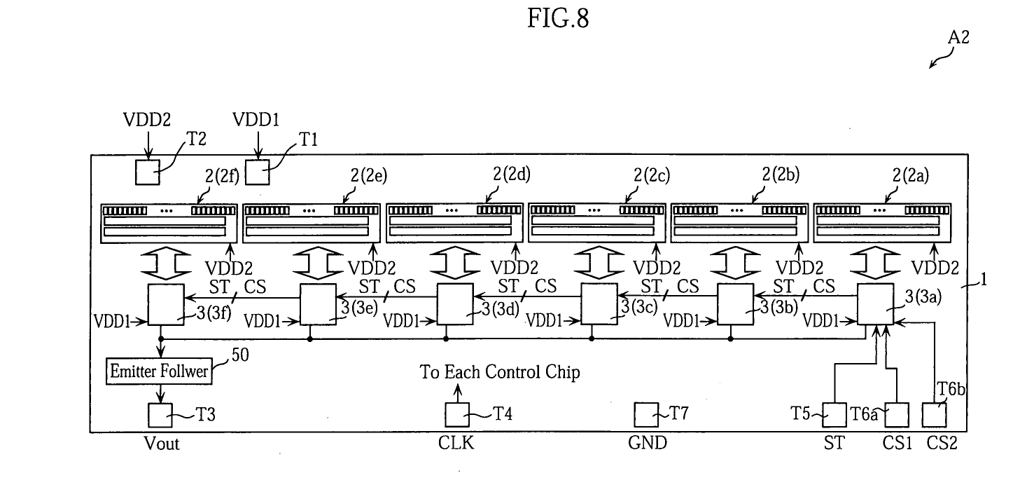

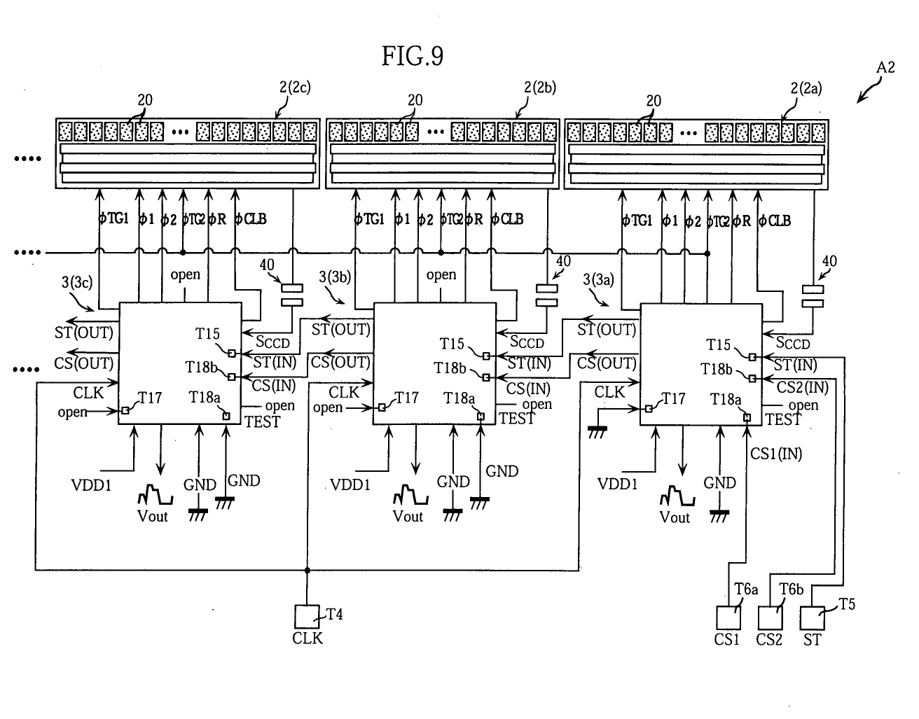

FIGS. 8 and 9 illustrate another embodiment of image reading apparatus according to of the present invention. In these figures, the elements which are identical or similar to those of the foregoing embodiment are designated by the same reference signs as those used in the foregoing embodiment.

The image reading apparatus A2 in this embodiment includes a plurality of CCD chips 2 (2a-2f) and control chips 3 (3a-3f) which are similar in structure to those of the foregoing embodiment. In this embodiment, however, the CCD chips 2 (2a-2f) and the control chips 3 (3a-3f) are not divided into blocks, as shown in FIG. 8, and the CCD chips 2 (2a-2f) are driven successively one by one.

Specifically, in the image reading apparatus A2, each of the control chips 3a-3e except the last control chip 3f outputs a start pulse ST to the subsequent control chip upon finishing the controlling of the relevant CCD chip 2. Thus, the control chips 3a-3f drives the CCD chips 2 successively so that successive image data for one line can be obtained through the terminal T3 on the substrate 1. Each of the control chips 3a-3e also outputs the resolution data CS to the subsequent control chip. The control chip 3 generates reset signals ΦR in a cycle corresponding to the specified resolution and outputs the reset signals ΦR to the relevant CCD chip 2.

The substrate 1 is provided with two terminals T6a and T6b for inputting resolution data. One-bit resolution data CS1 or CS2 is inputted from a controller (not shown) into each of the terminals T6a and T6b as parallel input. As shown in FIG. 9, the resolution data CS1 and CS2 inputted to the terminals T6a and T6b can be inputted into the first and the second resolution data input terminals T18a and T18b of the control chip 3a as parallel input. Unlike the foregoing embodiment, the mode setting terminal T17 is grounded so that the control chip 3a is set to the first mode. Therefore, the first and the second resolution data input terminals T18a and T18b function as input terminals for the parallel resolution data CS1 and CS2.

The control chips 3b-3f are set to the second mode, with the respective mode setting terminals T17 kept open. Therefore, the second resolution data input terminal T18b receives the serial resolution data CS from the previous control chip. In this embodiment, the first resolution data input terminals T18a of the control chips 3b-3f are grounded to allow the image reading at the resolution of 1200 dpi. However, the first resolution data input terminals T18a may be set open to inhibit the image reading at 1200 dpi.

As noted above, the image reading apparatus A2 differs from the image reading apparatus A1 in that the first control chip 3a receives parallel resolution data CS1 and CS2. However, the generation of reset signals ΦR in each of the control chips 3 in the image reading apparatus A2 is performed similarly to the image reading apparatus A1. Therefore, in the image reading apparatus A2 again, the image reading at the resolution selected from the four options can be performed properly, and the same advantages as those of the image reading apparatus A1 can be obtained.

The present invention is not limited to the foregoing embodiments, and the structures of the image reading apparatus and the control chips of the present invention may be modified in various ways.

For instance, in the present invention, the number of resolution options and the specific resolution values are not limitative. More than four resolution options can be provided by using a larger bit of resolution data. When the plurality of image sensor chips are divided into blocks for driving on a block basis, the number of blocks is not limitative.

Moreover, in the image reading apparatus according to the present invention, use may be made of image sensor chips which differ in structure from the CCD image sensor chip 2 of the foregoing embodiments.

1. An image reading apparatus comprising:
a plurality of image sensor chips each of which includes a plurality of photoelectric conversion elements and performs outputting of electric charge accumulated due to light received by the photoelectric conversion elements and resetting of the accumulated electric charge; and
a plurality of control chips for controlling operation of the image sensor chips;
wherein each of the control chips includes a resolution data input section to which resolution data to specify resolution is inputted, and also includes a reset signal generator for generating a reset signal for performing the resetting of the electric charge in a cycle corresponding to the resolution data inputted into the resolution data input section.

2. The image reading apparatus according to claim 1, wherein each of the control chips comprises a resolution void terminal for selectively inhibiting image reading at a predetermined resolution, the image reading at the predetermined resolution being inhibited when the resolution void terminal is held in a first wiring state but being enabled when the resolution void terminal is held in a second wiring state different from the first wiring state.

3. The image reading apparatus according to claim 1, wherein the resolution data input section comprises a first input terminal and a second input terminal, and
wherein each of the control chips is selectively set to a first mode and a second mode, the first mode permitting parallel input of the resolution data into the first input terminal and the second input terminal, the second mode permitting serial input of the resolution data into the second input terminal.

4. The image reading apparatus according to claim 3, wherein each of the control chips comprises a mode setting terminal for selection of the first mode and the second mode, and
wherein only one of the first mode and the second mode is selected when the mode setting terminal is grounded.

5. The image reading apparatus according to claim 3, wherein image reading at a predetermined resolution is inhibited when the second mode is selected and the first input terminal is held in a predetermined wiring state.

6. The image reading apparatus according to claim 1, wherein each of the image sensor chips is a CCD image sensor chip including photodiodes, a line memory and an analog shift register; and
wherein each of the control chips generates signals for causing the photodiodes to transmit electric charge to the line memory and the analog shift register and signals for causing the analog shift register to output signals, the signals outputted from the analog shift register being inputted into the control chip.

7. The image reading apparatus according to claim 1, wherein the control chips include amplifiers for amplifying signals outputted from the image sensor chips, and
wherein a reference voltage is applied to the amplifiers in parallel from a common power supplier.

8. A control chip for controlling driving of an image sensor chip, the control chip comprising:
a resolution data input section to which resolution data to specify resolution is inputted; and
a reset signal generator for generating a reset signal for causing the image sensor chip to reset accumulated electric charge in a cycle corresponding to the resolution data inputted into the resolution data input section.

9. The control chip according to claim 8, further comprising a resolution void terminal, wherein image reading at a predetermined resolution is inhibited when the resolution void terminal is held in a predetermined wiring state.
